(19) United States
(12) Patent Application Publication
(10) Pub. No.: US 2023/0371342 A1
(43) Pub. Date: Nov. 16, 2023

(54) DISPLAY DEVICE AND METHOD OF MANUFACTURING DISPLAY DEVICE

(71) Applicant: Japan Display Inc., Tokyo (JP)

(72) Inventors: Hiroshi TABATAKE, Tokyo (JP); Hiroyuki KIMURA, Tokyo (JP)

(73) Assignee: Japan Display Inc., Tokyo (JP)

(21) Appl. No.: 18/314,169

(22) Filed: May 9, 2023

(30) Foreign Application Priority Data
May 11, 2022 (JP) 2022-078308

(51) Int. Cl. H01L 51/00

(52) U.S. Cl. CPC H10K 59/65; H10K 59/871; H10K 71/166

(57) ABSTRACT

According to one embodiment, a display device includes a base, a lower electrode disposed in a first region on the base, a rib covering a part of the lower electrode and including an aperture overlapping the first region, a partition including a lower portion disposed on the rib and an upper portion protruding from a side surface of the lower portion, which compartmentalizes the first region and a second region different from the first region, an organic layer disposed in the first region and in contact with the lower electrode via the aperture and an upper electrode disposed on the organic layer, and the organic layer and the upper electrode are not disposed in the second region.

### CROSS-REFERENCE TO RELATED APPLICATIONS

This application is based upon and claims the benefit of priority from Japanese Patent Application No. 2022-078308, filed May 11, 2022, the entire contents of which are incorporated herein by reference.

### FIELD

Embodiments described herein relate generally to a display device and a method of manufacturing the display device.

### BACKGROUND

In recent years, a display device in which an organic light-emitting diode (OLED) is applied as a display element has been put to practical use, and it is known that an electronic device such as smartphones, for example, are equipped with such a display device.

In such an electronic device, by adopting a structure in which a camera is placed behind the display device (display area), the display area can be expanded to the area entirely overlapping the camera.

However, in such a structure, it is required that light enters the camera (the image sensor of the camera) via the display device, and therefore a sufficient light transmittance need to be secured in the display device (the area of the display area that overlaps the camera).

### BRIEF DESCRIPTION OF THE DRAWINGS

FIG. 1 is a diagram showing a configuration example of a display device according to an embodiment.

FIG. 2 is a diagram showing an example of layout of subpixels.

FIG. 3 is a cross-sectional view schematically showing the display device, taken along line III-III in FIG. 2.

FIG. 4 is a cross-sectional view schematically showing a partition.

FIG. 5 is a cross-sectional view schematically illustrating a display element formed by using a partition.

FIG. 6 is a cross-sectional view schematically illustrating a display element formed by using a partition.

FIG. 7 is a cross-sectional view schematically illustrating a display element formed by using a partition.

FIG. 8 is a plan view showing a part of an electronic device in which a display device is built.

FIG. 9 is a diagram for illustrating pixels located in a position overlapping a camera.

FIG. 10 is a cross-sectional view schematically showing a region located in a position overlapping a camera of a display device according to a comparative example of the embodiment.

FIG. 11 is a diagram illustrating an outline of a method of manufacturing the display device according to the embodiment.

FIG. 12 is another diagram illustrating the outline of the method of manufacturing the display device according to the embodiment.

FIG. 13 is a cross-sectional view schematically showing a region located in a position overlapping a camera of a display device according to the embodiment.

### DETAILED DESCRIPTION

In general, according to one embodiment, a display device includes a base, a lower electrode disposed in a first region on the base, a rib covering a part of the lower electrode and including an aperture overlapping the first region, a partition including a lower portion disposed on the rib and an upper portion protruding from a side surface of the lower portion, which compartmentalizes the first region and a second region different from the first region, an organic layer disposed in the first region and in contact with the lower electrode via the aperture and an upper electrode disposed on the organic layer, and the organic layer and the upper electrode are not disposed in the second region.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction, a direction along the Y axis is referred to as a second direction and a direction along the Z axis is referred to as a third direction. Further, viewing the elements parallel to the third direction Z is referred to as plan view.

The display device according to this embodiment is an organic electroluminescent display device including an organic light-emitting diode (OLED) as a display element, and can be mounted on electronic devices such as smartphones and the like. Note that the electronic device according to this embodiment in which the display device is mounted may be electronic devices other than smartphones (for example, tablet terminals, etc.)

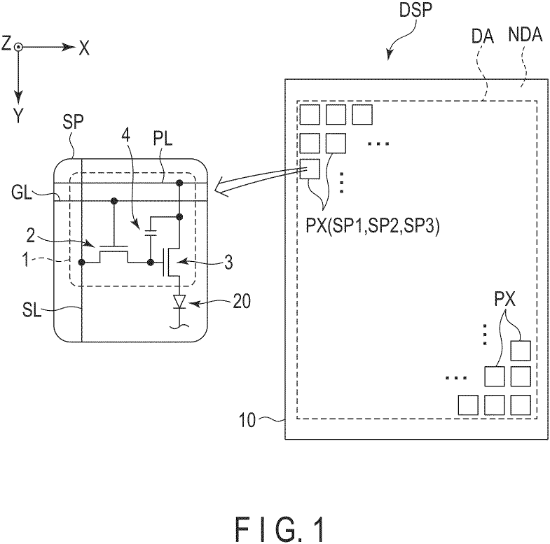

FIG. 1 shows a configuration example of the display device DSP according to this embodiment. The display device DSP includes a display area DA which displays images and a non-display area NDA surrounding the display area DA on an insulating base 10. The base 10 may be glass or a flexible resin film.

In this embodiment, the shape of the base 10 in plan view is rectangular. Note here that the shape of the base 10 in plan view is not limited to a rectangle, but may be other shapes such as a square, circle or oval.

The display area DA includes a plurality of pixels PX arrayed (disposed) in a matrix along the first direction X and the second direction Y. The pixels PX each include a plurality of subpixels SP. For example, the pixels PX each include a red subpixel SP1, a green subpixel SP2 and a blue subpixel SP3. Note that the pixels PX may each include, in addition to the subpixels SP1, SP2 and SP3, a subpixel SP of some other color such as white. Or, the pixels PX may each include subpixels SP of other colors in place of any of the subpixels SP1, SP2 and SP3.

The subpixels SP each includes a pixel circuit 1 and a display element 20 driven by the pixel circuit 1. The pixel circuit 1 includes a pixel switch 2, a drive transistor 3 and a capacitor 4. The pixel switch 2 and the drive transistor 3 are switching elements constituted by thin-film transistors, for example.

A gate electrode of the pixel switch 2 is connected to a scanning line GL. One of source and drain electrodes of the pixel switch 2 is connected to a signal line SL, and the other is connected to a gate electrode of the drive transistor 3 and the capacitor 4. In the drive transistor 3, one of source and drain electrodes is connected to a power line PL and capacitor 4, and the other is connected to the display element 20.

The configuration of the pixel circuit 1 is not limited to that of the example shown in FIG. 1. For example, the pixel circuit 1 may include more thin-film transistors and capacitors.

The display element 20 is an organic light-emitting diode (OLED) as a light emitting element. For example, the subpixel SP1 contains a display element 20 which emits light in a wavelength range of a red color, the subpixel SP2 contains a display element 20 which emits light in a wavelength range of a green color, and the subpixel SP3 contains a display element 20 which emits light in a wavelength range of a blue color.

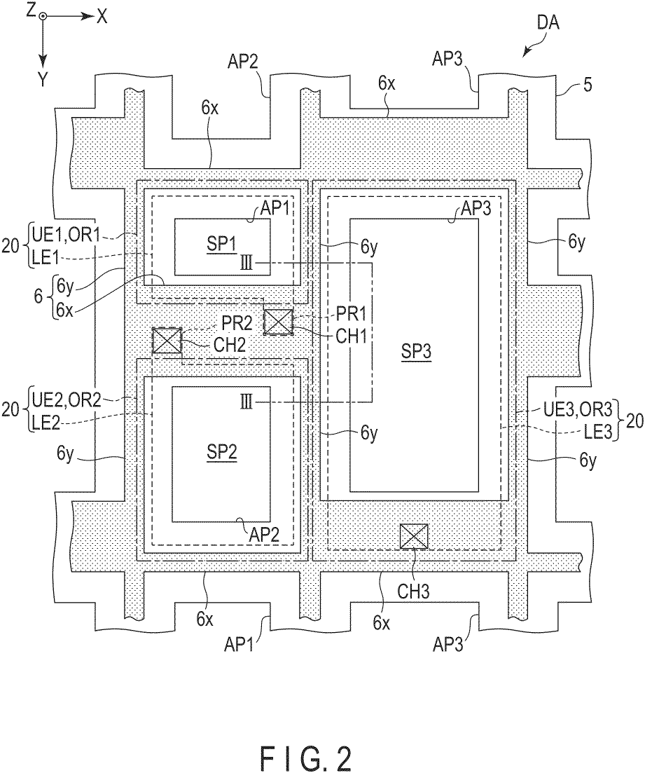

FIG. 2 shows an example of layout of subpixels SP1, SP2 and SP3. In the example illustrated in FIG. 2, the subpixels SP1 and SP2 are aligned along the second direction Y. Further, the subpixels SP1 and SP2 are each aligned with subpixel SP3 along the first direction X.

When the subpixels SP1, SP2 and SP3 are arranged in such a layout as shown in FIG. 2, rows in each of which the subpixels SP1 and SP2 are arranged alternately along the second direction Y and rows in each of which a plurality of subpixels SP3 are arranged repeatedly along the second direction Y are formed in the display area DA. These rows are alternately arranged along the first direction X.

The layout of the subpixels SP1, SP2 and SP3 is not limited to that of the example shown in FIG. 2. As another example, the subpixels SP1, SP2 and SP3 in each pixel PX may be arranged in order along the first direction X.

In the display area DA, a Rib 5 and a partition 6 are disposed. The rib 5 includes apertures AP1, AP2 and AP3 in the subpixels SP1, SP2 and SP3, respectively. In the example illustrated in FIG. 2, the apertures AP2 are larger in size than the apertures AP1, and the apertures AP3 are larger than the aperture AP2. The partition 6 is disposed at the boundaries of each adjacent pair of the subpixels SP and overlaps the rib 5 in plan view.

The partition 6 includes a plurality of first partitions 6x extending along the first direction X and a plurality of second partitions 6y extending along the second direction Y. The first partitions 6x are each disposed between each respective pair of apertures AP1 and AP2 adjacent to each other along the second direction Y and between each respective pair of apertures AP3 adjacent to each other along the second direction Y. The second partitions 6y are each disposed between each respective pair of apertures AP1 and AP3 adjacent to each other along the first direction X and between each respective pair of apertures AP2 and AP3 adjacent to each other along the first direction X.

In the example illustrated in FIG. 2, the first partitions 6x and the second partitions 6y are connected to each other. With this structure, the partition 6 as a whole is formed into a lattice shape which surrounds the apertures AP1, AP2 and AP3. The partition 6 may as well include apertures in the subpixels SP1, SP2 and SP3, respectively, as in the case of the rib 5.

That is, in this embodiment, the rib 5 and the partition 6 are arranged to compartmentalize the subpixels SP1, SP2 and SP3 one from another.

The subpixels SP1 each includes a lower electrode LE1, an upper electrode UE1 and an organic layer OR1, each of which overlap the respective aperture AP1. The subpixel SP2 each includes a lower electrode LE2, an upper electrode UE2 and an organic layer OR2, each of which overlap the respective apertures AP2. The subpixels SP3 each includes a lower electrode LE3, an upper electrode UE3 and an organic layer OR3, each of which overlap the respective aperture AP3. In the example illustrated in FIG. 2, the outlines of the upper electrode UE1 and the organic layer OR1 match each other, the outlines of the upper electrode UE2 and the organic layer OR2 match each other, and the outlines of the upper electrode UE3 and the organic layer OR3 match each other.

The lower electrode LE1, the upper electrode UE1 and the organic layer OR1 constitute the display element 20 of the subpixel SP1. The lower electrode LE2, the upper electrode UE2 and the organic layer OR2 constitute the display element 20 of the subpixel SP2. The lower electrode LE3, the upper electrode UE3 and the organic layer OR3 constitute the display element 20 of the subpixel SP3.

The lower electrode LE1 is connected to the pixel circuit 1 that drives the subpixel SP1 (the display element 20 thereof) via a contact hole CH1. The lower electrode LE2 is connected to the pixel circuit 1 that drives the subpixel SP2 (the display element 20 thereof) via a contact hole CH2. The lower electrode LE3 is connected to the pixel circuit 1 that drives the subpixel SP3 (the display element 20 thereof) via a contact hole CH3.

In the example illustrated in FIG. 2, the contact holes CH1 and CH2 entirely overlap the first partition 6x located between the apertures AP1 and AP2 adjacent to each other along the second direction Y. The contact hole CH3 entirely overlaps the first partition 6x located between two apertures AP3 adjacent to each other along the second direction Y. As another example, at least a part of the contact holes CH1, CH2 and CH3 may not overlap the first partition 6x.

In the example illustrated in FIG. 2, the lower electrodes LE1 and LE2 includes protrusions PR1 and PR2, respectively. The protrusion PR1 protrudes from the body of the lower electrode LE1(, which is a part overlapping the aperture AP1) toward the contact hole CH1. The protrusion PR2 protrudes from the body of the lower electrode LE2(, which is a part overlapping the aperture AP2) toward the contact hole CH2. The contact holes CH1 and CH2 overlap the protrusions PR1 and PR2, respectively.

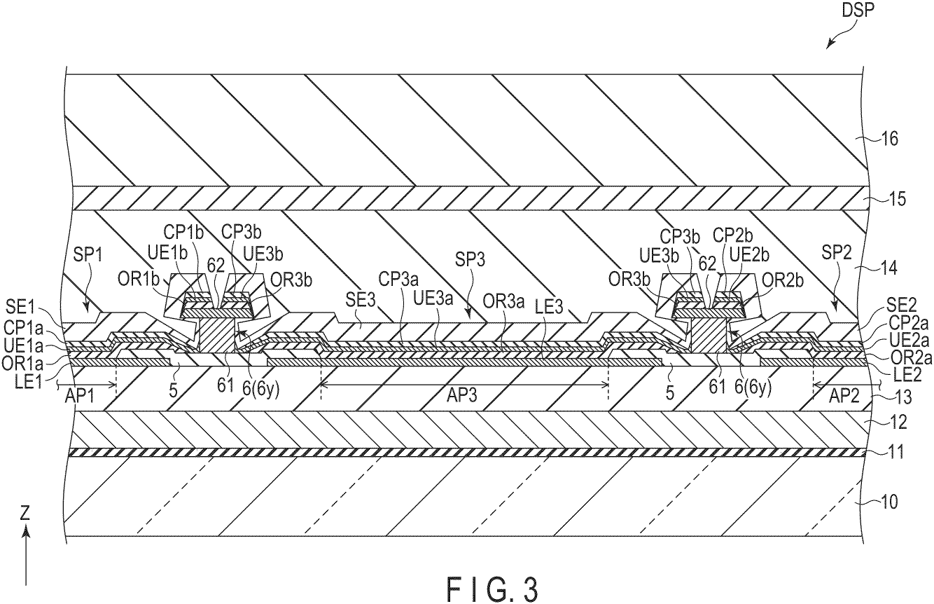

FIG. 3 is a schematic cross-sectional view of the display device DSP taken along line III-III in FIG. 2. In the display device DSP, an insulating layer 11, referred to as an undercoat layer, is disposed on the base 10 having light transparency, such as of glass described above (that is, on a surface on a side where the display element 20 and the like are disposed).

The insulating layer 11 has a three-layer stacked structure including, for example, a silicon oxide film (SiO), a silicon nitride film (SiN) and a silicon oxide film (SiO). Note that the insulating layer 11 is not limited to a three-layer stacked structure, but may have a stacked structure of three or more layers, or may have a single-layer structure or a two-layer stacked structure.

On the insulating layer 11, a circuit layer 12 is disposed. The circuit layer 12 includes various types of circuits and wiring lines that drive the subpixels SP (SP1, SP2 and SP3) such as the pixel circuit 1, scanning line GL, signal line SL and power line PL shown in FIG. 1. The circuit layer 12 is covered by an insulating layer 13.

The insulating layer 13 functions as a planarization film that planarizes the unevenness caused by the circuit layer 12. Although not shown in FIG. 3, the contact holes CH1, CH2 and CH3 described above are provided in the insulating layer 13.

The lower electrodes LE (LE1, LE2 and LE3) are disposed on the insulating layer 13. The rib 5 is disposed over the insulating layer 13 and the lower electrode LE. An end portion (a part) of the lower electrode LE is covered by the rib 5.

The partition 6 includes a lower portion 61 disposed on the rib 5 and an upper portion 62 covering an upper surface of the lower portion 61. The upper portion 62 has a width greater than that of the lower portion 61 in the first direction X as well as the second direction Y. With this configuration, the partition 6 has such a shape that both ends of the upper portion 62 protrude beyond side surfaces of the lower portion 61. Such a shape of the partition 6 may as well be referred to as an overhang shape.

The organic layers OR (OR1, OR2 and OR3) and the upper electrodes UE (UE1, UE2 and UE3) constitute the display elements 20, respectively, together with the lower electrodes LE (LE1, LE2 and LE3) described above. Here, as shown in FIG. 3, the organic layer OR1 includes a first organic layer OR1a and a second organic layer OR1b spaced apart from each other. The upper electrode UE1 includes a first upper electrode UE1a and a second upper electrode UE1b spaced apart from each other. The first organic layer OR1a is in contact with the lower electrode LE1 via the aperture AP1, and covers a part of the rib 5 as well. The second organic layer OR1b is located on the upper portion 62. The first upper electrode UE1a opposes the lower electrode LE1 and covers the first organic layer OR1a. Further, the first upper electrode UE1a is in contact with a side surface of the lower portion 61. The second upper electrode UE1b is located above the partition 6 and covers the second organic layer OR1b.

Moreover, as shown in FIG. 3, the organic layer OR2 includes a first organic layer OR2a and a second organic layer OR2b spaced apart from each other. The upper electrode UE2 includes a first upper electrode UE2a and a second upper electrode UE2b spaced apart from each other. The first organic layer OR2a is in contact with the lower electrode LE2 via the aperture AP2 and covers a part of the rib 5. The second organic layer OR2b is located on the upper portion 62. The first upper electrode UE2a opposed the lower electrode LE2 and covers the first organic layer OR2a. Further, the first upper electrode UE2a is in contact with the side surface of the lower portion 61. The second upper electrode UE2b is located above the partition 6 and covers the second organic layer OR2b.

As shown in FIG. 3, the organic layer OR3 includes a first organic layer OR3a and a second organic layer OR3b spaced apart from each other. The upper electrode UE3 includes a first upper electrode UE3a and a second upper electrode UE3b spaced apart from each other. The first organic layer OR3a is in contact with the lower electrode LE3 via the aperture AP3 and covers a part of the rib 5. The second organic layer OR3b is located on the upper portion 62. The first upper electrode UE3a opposes the lower electrode LE3 and covers the first organic layer OR3a. Further, the first upper electrode UE3a is in contact with a side surface of the lower portion 61. The second upper electrode UE3b is located above the partition 6 and covers the second organic layer OR3b.

In the example illustrated in FIG. 3, the subpixels SP1, SP2 and SP3 include cap layers CP1, CP2 and CP3 (optical path adjusting layers), respectively, for adjusting the optical properties of the light emitted by the light-emitting layers of the organic layers OR1, OR2 and OR3.

The cap layer CP1 includes a first cap layer CP1a and a second cap layer CP1b spaced apart from each other. The first cap layer CP1a is located in the aperture AP1 and disposed on the first upper electrode UE1a. The second cap layer CP1b is located above the partition 6 and disposed on the second upper electrode UE1b.

The cap layer CP2 includes a first cap layer CP2a and a second cap layer CP2b spaced apart from each other. The first cap layer CP2a is located in the aperture AP2 and disposed on the first upper electrode UE2a. The second cap layer CP2b is located above the partition 6 and disposed on the second upper electrode UE2b.

The cap layer CP3 includes a first cap layer CP3a and a second cap layer CP3b spaced apart from each other. The first cap layer CP3a is located in the aperture AP3 and disposed on the first upper electrode UE3a. The second cap layer CP3b is located above the partition 6 and disposed on the second upper electrode UE3b.

On the subpixels SP1, SP2 and SP3, sealing layers SE1, SE2 and SE3 are disposed respectively. The sealing layer SE1 continuously covers members of the subpixel SP1, which include the first cap layer CP1a, the partition 6 and the second cap layer CP1b. The sealing layer SE2 continuously covers members of the subpixel SP2, which include the first cap layer CP2a, the partition 6 and the second cap layer CP2b. The sealing layer SE3 continuously covers members of the subpixel SP3, which include the first cap layer CP3a, the partition 6 and the second cap layer CP3b.

In the example illustrated in FIG. 3, the second organic layer OR1b, the second upper electrode UE1b, the second cap layer CP1b and the sealing layer SE1 on the partition 6 between the subpixels SP1 and SP3 are separated from the second organic layer OR3b, the second upper electrode UE3b, the second cap layer CP3b and the sealing layer SE3 on the partition 6. Further, the second organic layer OR2b, the second upper electrode UE2b, the second cap layer CP2b and the sealing layer SE2 on the partition 6 between the subpixels SP2 and SP3 are separated from the second organic layer OR3b, the second upper electrode UE3b, the second cap layer CP3b and the sealing layer SE3 on the partition 6.

The sealing layers SE1, SE2 and SE3 are covered by a resin layer 14 (planarization layer). The resin layer 14 is covered by a sealing layer 15. Further, the sealing layer 15 is covered by a resin layer 16.

The insulating layer 13 and the resin layers 14 and 16 are formed of organic materials. The rib 5 and the sealing layer 15 and SE (SE1, SE2 and SE3) are formed of, for example, inorganic materials including silicon nitride (SiNx).

The lower portion 61 of the partition 6 has conductivity. The upper portion 62 of the partition 6 may as well be formed conductive. The lower electrode LE may be formed of a transparent conductive oxide such as indium tin oxide (ITO) or may have a multilayer stacked structure of a metal material such as silver (Ag) and a conductive oxide. The upper electrode UE is formed of a metal material such as an alloy of magnesium and silver (MgAg), for example. The upper electrode UE may as well be formed of a conductive oxide such as ITO.

When the potential of the lower electrode LE is relatively higher than that of the upper electrode UE, the lower electrode LE corresponds to an anode and the upper electrode UE corresponds to a cathode. Or, when the potential of the upper electrode UE is relatively higher than that of the lower electrode LE, the upper electrode UE corresponds to an anode and the lower electrode LE corresponds to a cathode.

The organic layer OR includes a pair of functional layers and a light-emitting layer disposed between these functional layers. For example, the organic layer OR has a structure in which a hole injection layer, a hole transport layer, an electron blocking layer, an emitting layer, a hole blocking layer, an electron transport layer and an electron injection layer are stacked one on another in order.

The cap layers CP (CP1, CP2 and CP3) are each formed, for example, from a multilayer body of a plurality of transparent thin films. The multilayer body may include, as the thin films, thin films formed of inorganic materials and thin films formed of organic materials. These thin films have refractive indices different from each other. The material of the thin films which constitute the multilayer body is different from the material of the upper electrode UE and also from the material of the sealing layers SE. Note here that the cap layers CP may be omitted.

To the partition 6, a common voltage is supplied. The common voltage is supplied to each of the upper electrodes UE (the first upper electrodes UE1a, UE2a and UE3a), which are in contact with the side surface of the lower portion 61. To the lower electrodes LE (LE1, LE2 and LE3), pixel voltages are supplied via the pixel circuits 1 of the subpixels SP (SP1, SP2 and SP3), respectively.

When a potential difference is created between the lower electrode LE1 and the upper electrode UE1, the light-emitting layer of the first organic layer OR1a emits light in a wavelength range of a red color. When a potential difference is created between the lower electrode LE2 and the upper electrode UE2, the light-emitting layer of the first organic layer OR2a emits light in a wavelength range of a green color. When a potential difference is created between the lower electrode LE3 and the upper electrode UE3, the light-emitting layer of the first organic layer OR3a emits light in a wavelength range of a blue color.

As another example, the light-emitting layers of the organic layers OR1, OR2 and OR3 may emit light of the same color (for example, white). In this case, the display device DSP may include color filters that convert the light emitted by the light-emitting layers into light of colors corresponding to the subpixels SP1, SP2 and SP3, respectively. Further, the display device DSP may include layers containing quantum dots that are excited by the light emitted by the light-emitting layers to generate light of colors corresponding to the subpixels SP1, SP2 and SP3, respectively.

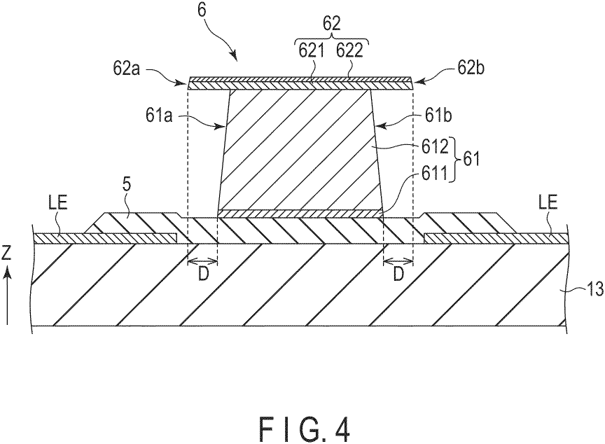

FIG. 4 is an enlarged cross-sectional view schematically showing the partition 6. In FIG. 4, elements other than the rib 5, the partition 6, the insulating layer 13 and the pair of lower electrodes LE are omitted from illustration. The pair of lower electrodes LE correspond to any of the lower electrodes LE1, LE2 and LE3 described above. The first partitions 6x and the second partitions 6y described above have the same structure as that of the partition 6 shown in FIG. 4.

In the example illustrated in FIG. 4, the lower portion 61 of the partition 6 includes a barrier layer 611 disposed on the rib 5 and a metal layer 612 disposed on the barrier layer 611. The barrier layer 611 is formed of a material different from that of the metal layer 612, that is, for example, a metal material such as molybdenum or the like. The metal layer 612 is formed thicker than the barrier layer 611. The metal layer 612 may be of a single-layer structure or a stacked structure of different metallic materials. For example, the metal layer 612 is formed, for example, by aluminum (Al).

The upper portion 62 is thinner than the lower portion 61. In the example illustrated in FIG. 4, the upper portion 62 includes a first layer 621 disposed on the metal layer 612 and a second layer 622 disposed on the first layer 621. For example, the first layer 621 is formed of titanium (Ti), whereas the second layer 622 is formed of ITO, for example.

In the example illustrated in FIG. 4, the width of the lower portion 61 decreases as the location is closer to the upper portion 62. In other words, side surfaces 61a and 61b of the lower portion 61 are inclined with respect to the third direction Z. Note here that the upper portion 62 includes an end portion 62a protruding from the side surface 61a and an end portion 62b protruding from the side surface 61b.

Here, the amount of protrusion of the end portions 62a and 62b from the side surfaces 61a and 61b is represented by D(, which will be referred to as the protrusion amount D of the partition 6, hereinafter) and is, for example, 2.0 µm or less. The protrusion amount D of the partition 6 in this embodiment corresponds to the distance between a respective lower edge of the side surface 61a (the barrier layer 611) and the end portion 62a and between a respective lower edge of the side surface 61b (the barrier layer 611) and the end portion 62 along the width direction of the partition 6 (the first direction X or second direction Y), which is orthogonal to the third direction Z.

The configuration of the partition 6 and the material of each member of the partition 6 may be selected as appropriate in consideration of, for example, the method of forming the partition 6 and the like.

In this embodiment, the partition 6 is formed to compartmentalize the subpixels SP in plan view. Here, the organic layer OR described above is formed, for example, by an anisotropic or directional vacuum deposition method. When the organic material for forming the organic layer OR is deposited over the entire base 10 with the partition 6 disposed therein, the organic layer OR is not substantially formed on the side surface of the partition 6 because the partition 6 has such a shape as shown in FIGS. 3 and 4. In this manner, the organic layer OR (the display elements 20) can be formed such as to be divided into each subpixel SP by the partition 6.

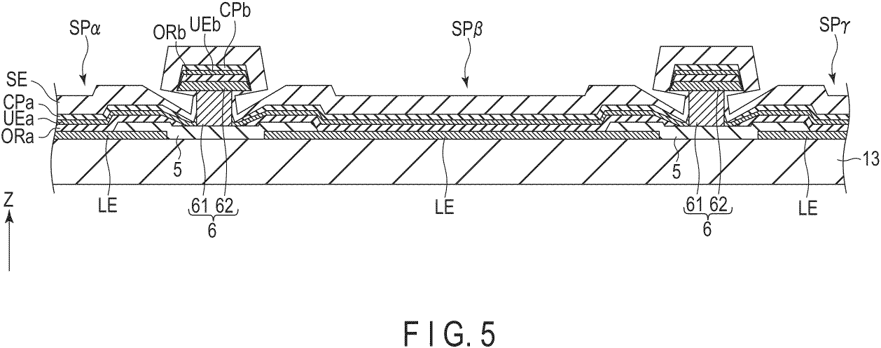

FIGS. 5 to 7 are each a schematic cross-sectional view to illustrate display elements 20 formed by using the partition 6. FIGS. 5 to 7 show subpixels SPα, SPβ and SPγ, which correspond to any of the subpixels SP1, SP2 and SP3.

First, with the partition 6 disposed as described above, the organic layer OR, the upper electrode UE, the cap layer CP and the sealing layer SE are formed by vapor deposition in order on the entire base 10 as shown in FIG. 5. The organic layer OR includes a light-emitting layer that emits light of a color corresponding to the subpixel SPα. With the overhanging partition 6, the organic layer OR is divided into a first organic layer ORa covering the lower electrode LE and a second organic layer ORb on the partition 6, the upper electrode UE is divided into a first upper electrode UEa covering the first organic layer ORa and a second upper electrode UEb covering the second organic layer ORb, and the cap layer CP is divided into a first cap layer CPa covering the first upper electrode UEa and a second cap layer CPb covering the second upper electrode UEb. The first upper electrode UEa is in contact with the lower portion 61 of the partition 6. The sealing layer SE continuously covers the first cap layer CPa, the second cap layer CPb and the partition 6.

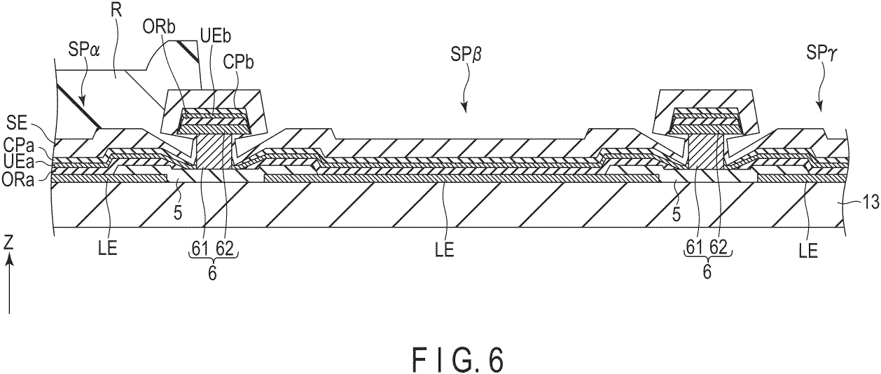

Next, as shown in FIG. 6, a resist R is formed on the sealing layer SE. The resist R covers the subpixel SPα. In other words, the resist R is disposed directly above the first organic layer ORa, the first upper electrode UEa and the first cap layer CPa, which are located in the subpixel SPα. The resist R is also located directly above the portion of the second organic layer ORb, the second upper electrode UEb and the second cap layer CPb on the partition 6 between the subpixel SPα and the subpixel SPβ, which is closer to the subpixel SPα. In other words, at least a part of the partition 6 is exposed from the resist R.

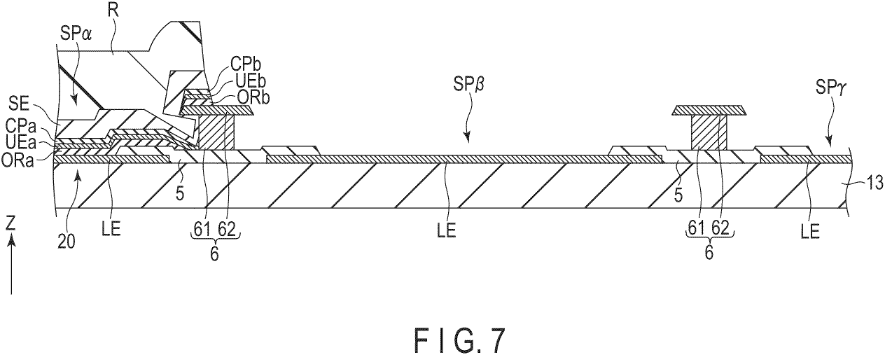

Further, by etching using the resist R as a mask, portions of the organic layer OR, the upper electrode UE, the cap layer CP and the sealing layer SE, which are exposed from the resist R are removed, as shown in FIG. 7. As a result, a display element 20 which includes the lower electrode LE, the first organic layer ORa, the first upper electrode UEa and the first cap layer CPa is formed in the subpixel SPα. On the other hand, in the subpixels SPβ and SPγ, the lower electrode LE is exposed. Note that the etching described above includes, for example, dry etching of the sealing layer SE, wet etching and dry etching of the cap layer CP, wet etching of the upper electrode UE, and dry etching of the organic layer OR.

After the display element 20 of the subpixel SPα is formed as described above, the resist R is removed and the display elements 20 of the subpixels SPβ and SPγ are formed in order as in the case of the subpixel SPα.

By exemplified above with respect to the subpixels SPα, SPβ and SPγ, the display elements 20 of the subpixels SP1, SP2 and SP3 are formed and further the resin layer 14, the sealing layer 15 and the resin layer 16 are formed, thereby realizing the configuration of the display device DSP shown in FIG. 3.

Here, let us assume the case where the display device DSP of this embodiment is used together with a camera, for example, in an electronic device such as a smartphone.

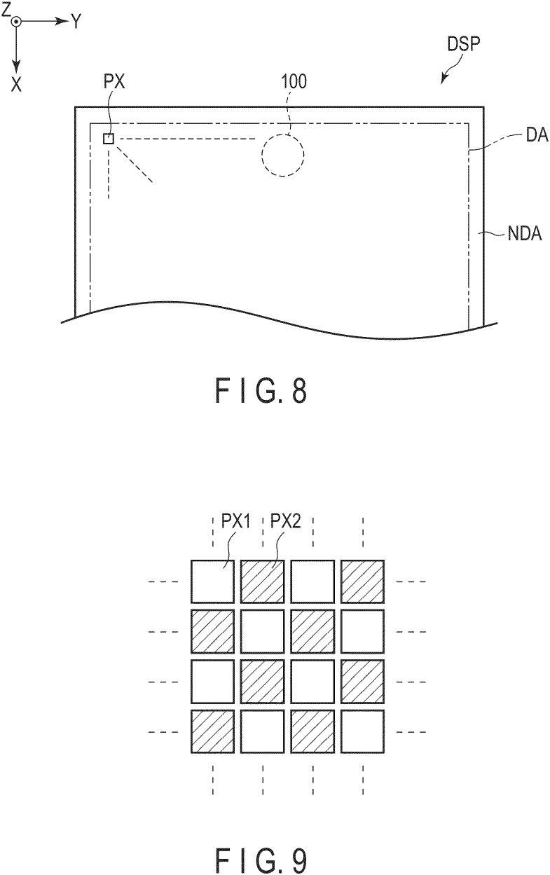

FIG. 8 is a plan view showing a part of an electronic device in which the display device DSP (display panel) of this embodiment is built. As described above, in the display device DSP, the display area DA includes a plurality of pixels PX arrayed in a matrix along the first direction X and the second direction Y. Further, the display device DSP includes a display surface includes a display area DA and a rear surface opposing the display surface(, which will be hereinafter referred to as the rear surface of the display device DSP). In an electronic device in which the display device DSP of this embodiment is built, it is assumed that the camera 100 is disposed on a side of a rear surface of the display device DSP.

In this case, as shown in FIG. 8, in order to expand the display area DA in the electronic device (display device DSP) (to expand the range of the display area DA), it is considered to place the camera 100 in a position overlapping the display area DA (that is, multiple pixels PX).

However, when the camera 100 is placed in a position overlapping the display area DA in plan view, the light transmittance of the region overlapping the camera 100 (that is, the region including the pixels PX) decreases due to the influence of the pixel circuit 1 and the lower electrode LE provided in each of the pixels PX that overlap the camera 100, and a sufficient amount of light may not be able to enter transmittance of the camera 100 via the display device DSP.

Under these circumstances, as shown in FIG. 9, for example, by adopting a configuration to thin out at least some of the plurality of pixels PX that are arranged in positions overlapping the camera 100, it is possible to improve the light transmittance in the region of the display area DA, which overlaps the camera 100(, which will be hereinafter referred to as “overlapping region”). Note that FIG. 9 shows a part of the overlapping region, and regions PX1 shown in FIG. 9 indicate regions area where pixels PX are placed and regions PX2 indicate regions where pixels PX are not provided (that is, the pixels PX are thinned out) .

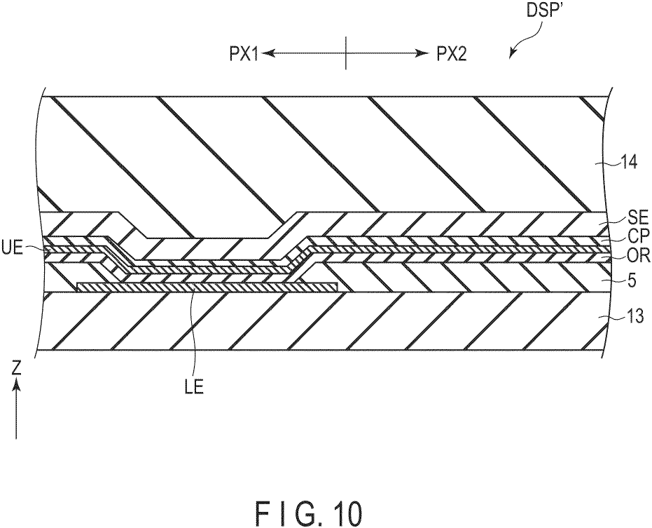

Here, FIG. 10 is a cross-sectional view schematically showing a display device DSP′ according to a comparative example of this embodiment. In FIG. 10, as a comparative example of the present embodiment, such a display device DSP′ is assumed that the above-described partition 6 is not disposed. Further, in FIG. 10, the base 10, the insulating layer 11, the circuit layer 12, the sealing layer 15 and the resin layer 16 are omitted from illustration.

In the display device DSP′ shown in FIG. 10, the lower electrode LE (and the pixel circuit 1) disposed in each region PX1 are not provided in the regions PX2, and thus the light transmittance in (the overlapping region including) the regions PX2 can be improved.

However, in the display device DSP′, the organic layer OR, the upper electrode UE and the cap layer CP are uniformly formed over the regions PX1 and PX2 by vapor deposition. As a result, the light transmittance in the regions PX2 may not be sufficiently improved due to the influence by the organic layer OR, the upper electrode UE and the cap layer CP.

By contrast, since the display device DSP of this embodiment is configured such that the partition 6 is disposed so as to compartmentalize (the subpixels SP included in each of) the pixels PX, and thus the organic layer OR, the upper electrode UE and the cap layer CP are formed separated between the pixels PX. Thus, for example, with the arrangement of the regions PX2, the organic layer OR, the upper electrode UE and the cap layer CP can be selectively removed, thereby making it possible to improve the light transmittance of the regions PX2.

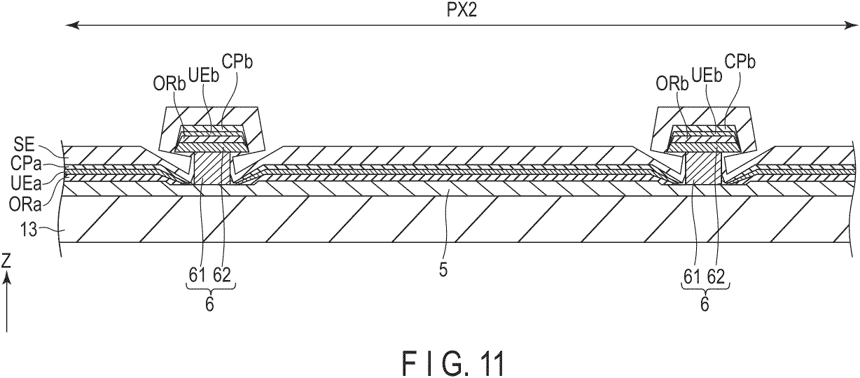

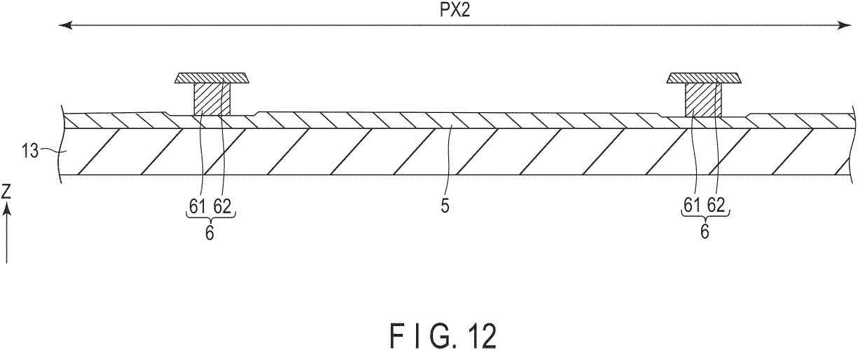

Now, with reference to FIGS. 11 and 12, an outline of a method (manufacturing process) of manufacturing the display device DSP according to this embodiment will be described. Note that in FIGS. 11 and 12, the regions PX2, which are located at positions overlapping the camera 100, will be mainly explained. Further, in this embodiment, it is assumed that in the regions PX2 as well where the pixels PX are thinned out, the partition 6 is disposed in the same pattern as that of the regions PX1 where the pixels PX are provided (that is, in a pattern such that the subpixels SP1, SP and SP3 are compartmentalized from each other). FIGS. 11 and 12 each illustrate the regions PX2 which include the regions each corresponding to each respective one of the subpixels SP1, SP2 and SP3, which are compartmentalized by the partition 6.

First, as shown in FIG. 11, organic layers OR (ORa and ORb), upper electrodes UE (UEa and UEb), cap layers CP (CPa and CPb) and a sealing layer SE are formed in order by vapor deposition in the regions PX2. Although not shown in FIG. 11, an organic layer OR, an upper electrode UE, a cap layer CP and a sealing layer SE are formed in a similar manner in the regions PX1 as illustrated in FIG. 5 referred to as above.

Here, as explained with reference to FIGS. 6 and 7 above, the display element 20 of the subpixel SPα is formed in the regions PX1 by etching using the resist R as a mask, whereas in the regions PX2, no resist R is formed and the sealing layer SE, the cap layer CP, the upper electrode UE and the organic layer OR are removed.

Here, the description is directed to the regions PX2 in the case where the display element 20 of the subpixel SPα is formed in each region PX1, but in the case where the display element 20 of the subpixel SPβ is formed in each region PX1, similarly, the organic layer OR, the upper electrode UE, the cap layer CP and the sealing layer SE, which are formed as shown in FIG. 11, are removed. This is also the case where the display element 20 of the subpixel SPɣ is formed in each of the regions PX1.

In the case of the manufacturing method of the display device DSP illustrated in FIGS. 11 and 12, the sealing layer SE is not disposed in the regions PX2, either. Further, since the pixels PX (the display elements 20 of the subpixels SP1, SP2 and SP3) are not disposed in the regions PX2 as described above, the pixel circuits 1 and the lower electrodes LE that drive the display elements 20 are not provided either. In this case, the rib 5 formed in the regions PX2 may not include an opening (an aperture AP) as shown in FIGS. 11 and 12. Note that FIGS. 11 and 12 show the rib 5 which does not include an aperture, but the rib 5 may include such an aperture.

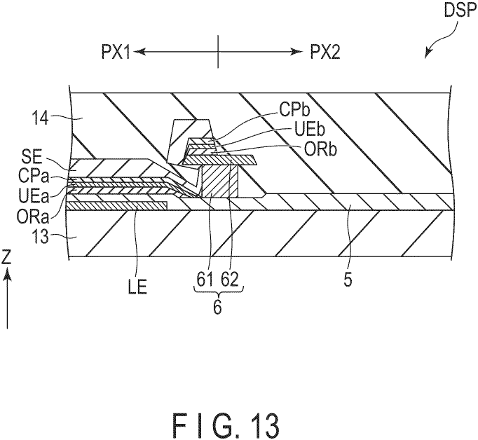

FIG. 13 shows a boundary portion between regions PX1 and PX2, which are located in positions overlapping the camera 100 of the display device DSP of this embodiment. In this embodiment, as shown in FIG. 13, the organic layer OR, the upper electrode UE and the cap layer CP (that is, the display element 20 of each subpixel SP) are disposed in each region PX1, whereas the organic layer OR, the upper electrode UE and the cap layer CP are not disposed in the regions PX2, and thus a display device DSP in which the resin layer 14 is stacked directly on top of the ribs 5 can be realized. Further, the resin layer 14 is in contact with side surfaces of the upper portion 62 and the lower portion 61 of the partition 6 located on a side of a region PX2.

As described above, the display device DSP of this embodiment includes a base 10, a lower electrode LE disposed in the regions PX1 (the first regions) on the base 10, a rib 5 which covers a part of the lower electrode LE and includes an aperture that overlapping the regions PX1, a partition including a lower portion 61 disposed on the rib 5 and an upper portion 62 protruding from a side surface of the lower portion 61, which compartmentalize the regions PX1 and the regions PX2 (the second regions) different from the regions PX1 from each other, an organic layer OR disposed in the regions PX1 so as to be in contact with the lower electrode through the aperture, and an upper electrode UE disposed on the organic layer OR, and the organic layer OR and the upper electrode UE are not disposed in the regions PX2. Note that the regions PX1 and PX2 in this embodiment are arranged in positions overlapping the camera 100 (image sensor) which light enters via the display device DSP.

In this embodiment, with the above-described configuration, the light transmittance of the regions PX2 can be improved, and as a result, the light transmittance in the overlapping region including the regions PX2 (the region of the display area DA, which overlaps the camera 100) can be enhanced. Further, in this embodiment, the configuration of the regions PX2 can be realized in the process of forming the display element 20 of each subpixel SP in the display area DA other than the regions PX2, and thus it is possible to efficiently improve the light transmittance.

Note that in this embodiment, the rib 5 can be formed so as not to include an aperture overlapping the regions PX2 as shown in FIGS. 11 and 12 above. With such a configuration, it is possible to suppress, for example, foreign matter such as moisture from entering the section underneath the rib 5(, which includes the circuit layer 12 and the like located below) through the aperture (that is, in other words, it is possible to improve the reliability of the display device DSP).

Furthermore, this embodiment is configured, in addition to the organic layer OR and the upper electrode UE described above, such that the cap layer CP and the sealing layer SE are not disposed in the regions PX2, thus making it possible to further improve the light transmittance.

It should be noted here that, for example, even in the display device DSP′ according to the comparative example of this embodiment described above, it is conceivable to increase the light transmittance (the amount of light transmission) in the overlapping region by increasing the aperture ratio (the area of the aperture) of the regions PX2, for example. However, it is difficult in designing to increase the aperture ratio.

By contrast, in this embodiment, the light transmittance can be increased while maintaining the aperture ratio (that is, without implementing design changes to increase the aperture ratio), and thus it has the advantageous effect of being highly feasible.

In addition, this embodiment is assumed on such a case as shown in FIG. 9 that there are equal number of regions PX1 and PX2. But if the number of regions PX1 (that is, pixels PX) is less, the display quality in the overlapping region will be undesirably degraded. On the other hand, the embodiment has such a configuration that can improve the light transmittance in the regions PX2, the ratio (number) of the regions PX1 in the overlapping region may be increased according to such improvement in light transmittance. With this configuration, it is possible to improve the display quality in the overlapping region while securing a predetermined light transmittance in the overlapping region.

Furthermore, this embodiment is described in connection with the configuration in which the regions PX1 and PX2 are disposed (formed) in units of pixel PX, but the regions PX1 and PX2 can as well be provided in units of subpixel SP. In other words, this embodiment may be configured such that at least some of the plurality of subpixels SP arranged in the overlapping region are thinned out.

Moreover, this embodiment is assumed on the case where (the image sensor of) the camera 100 is placed on the rear surface of the display device DSP, but this embodiment may as well be applicable to such a case that a sensor including a light-receiving element and the like, that convert incident light into an electrical signal or a device including such a sensor is placed on the rear surface of the display device DSP. In other words, it suffices if the display device DSP of this embodiment is configured to improve the light transmittance in a predetermined region of the display area DA, and the member placed on the rear surface of the display device DSP is not limited to those mentioned above.

All display devices and manufacturing methods for display devices, which are implementable with arbitrary changes in design by a person of ordinary skill in the art based on the display devices and the manufacturing methods for display devices described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A display device comprising:
a base;
a lower electrode disposed in a first region on the base;
a rib covering a part of the lower electrode and including an aperture overlapping the first region;
a partition including a lower portion disposed on the rib and an upper portion protruding from a side surface of the lower portion, which compartmentalizes the first region and a second region different from the first region;
an organic layer disposed in the first region and in contact with the lower electrode via the aperture; and
an upper electrode disposed on the organic layer, wherein
the organic layer and the upper electrode are not disposed in the second region.

2. The display device of claim 1, wherein
the first and second regions are disposed in respective positions overlapping a light-receiving element that receives light via the display device.

3. The display device of claim 1, wherein
the rib does not include an aperture overlapping the second region.

4. The display device of claim 1, further comprising:
a cap layer disposed on the upper electrode; and
a sealing layer disposed on the cap layer, wherein
the cap layer and the sealing layer are not disposed in the second region.

5. A method of manufacturing a display device, comprising:
forming a lower electrode in a first region on a base;
forming a rib covering a part of the lower electrode and including an aperture overlapping the first region;
forming a partition including a lower portion disposed on the rib and an upper portion protruding from a side surface of the lower portion, which compartmentalizes the first region and a second region different from the first region;
forming an organic layer on the first and second regions;
forming an upper electrode on the organic layer;
forming a cap layer on the upper electrode;
forming a sealing layer on the cap layer;
forming a resist in the first region on the sealing layer; and
removing the sealing layer, the cap layer, the upper electrode and the organic layer formed in the second region using the resist as a mask.
